(19) United States
(12) Patent Application Publication
(10) Pub. No.: US 2017/0280551 A1
(43) Pub. Date: Sep. 28, 2017

(54) Heat radiation shielding device

(71) Applicants: LE HOLDINGS (BEIJING) CO., LTD., Beijing (CN); LE SHI ZHI XIN ELECTRONIC TECHNOLOGY (TIANJIN) LIMITED, Beijing (CN)

(72) Inventor: Erhu MA, Beijing (CN)

(21) Appl. No.: 15/242,079

(22) Filed: Aug. 19, 2016

Related U.S. Application Data
(63) Continuation of application No. PCT/CN2016/088423, filed on Jul. 4, 2016.

(30) Foreign Application Priority Data
Mar. 23, 2016 (CN) 2016202287994

(51) Int. Cl. H05K 1/02

(52) U.S. Cl. CPC H05K 1/0203

(57) ABSTRACT

A heat radiation shielding device comprising a heat sink is disclosed, comprising a substrate with a conductive base and cooling fins configured on the substrate; a conductive frame, fixed on periphery of the base of the substrate of the heat sink, forming a hood structure closed on three sides and open on one side with the substrate of the heat sink; and a ground element, configured around the electronic components on the circuit board, where the conductive frame is conductive frame on the open side of the hood structure, and engaged to the ground element, forming an electric connection with the circuit board.

### CROSS REFERENCE TO RELATED APPLICATIONS

The present application is a continuation of PCT application which has an application number of PCT/CN2016/088423 and was filed on Jul. 4, 2016. This application claims priority to Chinese Patent Application No. 201620228799.4, entitled “HEAT RADIATION SHIELDING DEVICE” submitted to the State Intellectual Property Office on Mar. 23, 2016, the whole content of which is integrated into the present application by citation.

### TECHNICAL FIELD

The present disclosure relates to the technical field of the electronic device, specifically, involving a heat radiation shielding device.

### BACKGROUD

With the fast development of the electronic technology, the integration level and packing density of electronic components are increasing. With the provision of powerful application functions, they also greatly increase the power consumption and heat radiation. High temperature affects the stability, liability and operation life of the electronic components greatly. Therefore, it has become an important aspect in the assembly of microelectronic product system to ensure a timely discharge of the heat generated by the heat radiating electronic components. Heat sink is an effective heat radiating manner that can effectively diffuse the heat generated by the electronic components.

Meanwhile, the increase in the integration level of the electronic components increases the number of electronic signals and the frequency, which incurs a greater number of electromagnetic compatibility problems. Shielding is an effective manner against the electromagnetic interference among high-speed signals. The current shielding manners usually configure shielding hoods around the components needing shield, and situate the electronic component within the shielding hoods.

In order to solve the above heat discharging and shielding problems, the current technologies usually use the heat sink and the shielding hood simultaneously. Due to the presence of shielding hood, the heat sink cannot contact heat radiating components directly. Meanwhile. in order to reduce the thermal contact resistances between the heat radiating components and the shielding hood and between the shielding hood and the heat sink, thermal interface materials are respectively needed to be respectively filled between the heat radiating components and the shielding hood and between the shielding hood and the heat sink. During the implementation of the present disclosure, the inventor found that in such a design, the heat generated from the heat radiating components should pass two thermal interface materials, and through the shielding hood before finally reaching the heat sink for discharge. This manner greatly reduces the heat radiating efficiency and increases the installation difficulty.

### SUMMARY

Considering the above problem, the present disclosure provides a heat radiation shielding device that overcomes or at least partially overcomes the above problem.

Embodiments of the present disclosure provide a heat radiation shielding device for shielding electronic components on a circuit board. The heat radiation shielding device comprises a heat sink, comprising a substrate with a conductive base and cooling fins configured on the substrate; a conductive frame, fixed on periphery of the base of the substrate of the heat sink, and forming a hood structure closed on three sides and open on one side together with the substrate of the heat sink; and a ground element, arranged around the electronic components on the circuit board, wherein the conductive frame is arranged on the open side of the hood structure, and engaged to the ground element, forming an electric connection with the circuit board.

In the heat radiation shielding device provided in the present disclosure, the ground element, the conductive frame and the substrate of the heat sink form a shielding hood, allowing a direct heat discharge of the heat radiating components via the heat sink, which not only meets the requirement of shielding the electromagnetic wave, but also achieves a satisfactory heat discharge effect. Meanwhile, the substrate of the heat sink also used as the top of the shielding hood saves the material.

The above elaboration is merely a general introduction on the technical solution of the present disclosure. In order to know the technical means of the present disclosure more clearly, so as to implement according to the description, and in order to make the above and other aims, features and advantages of the present disclosure clearer and easier to be understood, specific embodiments of the present disclosure are to be exemplified as follows.

### BRIEF DESCRIPTION OF THE DRAWINGS

Through the following detailed illustration on the preferable embodiments, various other advantages and merits become clearer to those skilled in the art. Drawings are merely used to illustrate the preferable embodiments, rather than limiting the present disclosure. Throughout the drawings, identical reference signs indicate identical components. Among the drawings:

FIG. 1 is a schematic diagram of a heat radiation shielding device provided in some embodiments of the present disclosure;

FIG. 2 is a schematic diagram of a heat radiation shielding device provided in some embodiments of the present disclosure.

### DETAILED DESCRIPTION

The example embodiments of the present publication are to be further elaborated in detail with reference to the accompanying drawings. The drawings show the example embodiments of the present publication, whereas it should be understood that the present publication can be implemented in various manners, and should not be limited by the embodiments elaborated herein. Instead, these embodiments are provided for clearer understanding of the present publication, and conveying the scope of the present publication completely to those skilled in the art.

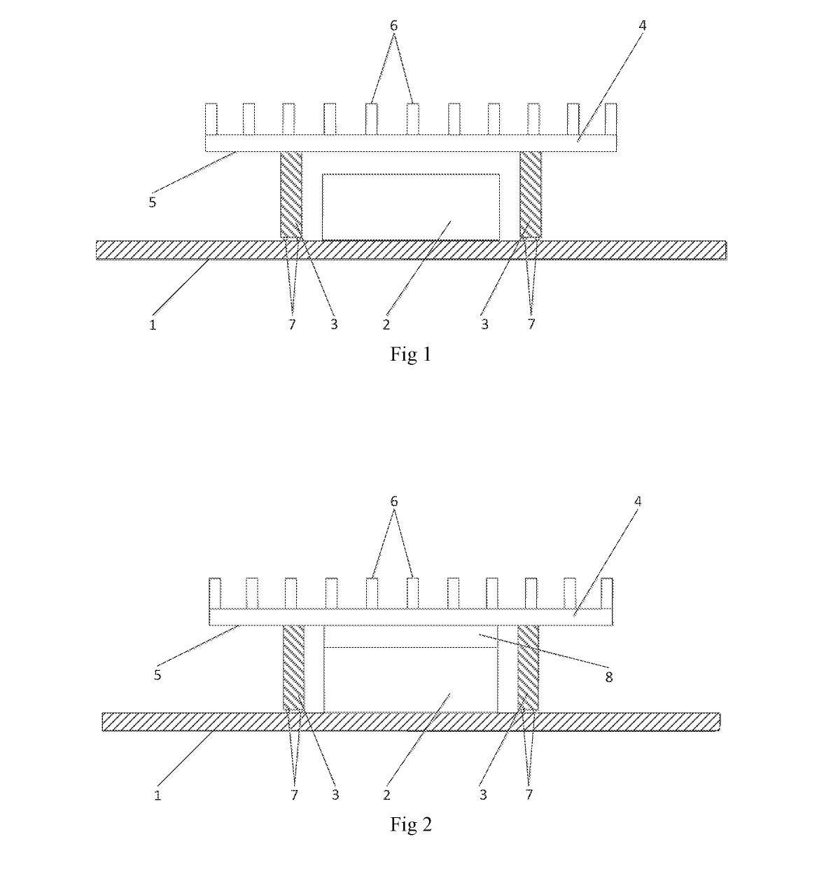

FIG. 1 is a schematic diagram of the structure of a heat radiation shielding device provided in an embodiment of the present disclosure. As shown in FIG. 1, a heat radiating electronic component 2 in need of shielding is configured on a circuit board 1. The heat radiation shielding device comprises a ground element 7, a conductive frame 3 and a heat sink 4, wherein the heat sink 4 comprises a substrate 5 with a conductive base and cooling fins 6 arranged on the substrate 5. The conductive frame 3 is fixed on periphery of the base of the substrate 5 of the heat sink, forming a hood structure closed on three sides and open on one side. The internal space of the hood structure should be greater than the surface area of the electronic component. The ground element 7 is arranged around the electronic component 2 on the circuit board circuit board 1. The conductive frame 3 is arranged e on the open side of the hood structure, and engaged to the ground element 7, forming an electric connection with the circuit board 1, and finally forming a closed shielding hood together with the substrate 5, conductive frame 3 and circuit board 1, with the electronic component 2 situating within the shielding hood.

The shape formed by the electronic component 2 around the electronic component 2 corresponds to the shape of the bottom surface of the conductive frame 3, which can be a circle, a rectangle, a square, other regular polygons or any geometric shape. The present disclosure does not specifically specify the shape formed by the ground element 7 around the electronic component 2.

The present example embodiment provides a heat radiation shielding device, wherein the ground element 7, conductive frame 3 and substrate 5 of heat sink 4 form a shielding hood, wherein the conductive frame 3 is selected from materials with excellent electrical conductivity, thermal conductivity and electromagnetic shielding property, such as metal material or conductive rubber. In one aspect, the electronic component 2 discharges the heat via the heat sink 4 and the conductive frame 3. In another aspect, the conductive frame 3 also has an electromagnetic shielding property. Furthermore, the substrate 5 of heat sink 4 is also used as the top of the shielding hood, which material economical.

In one embodiment of the present disclosure, the conductive frame 3 is a rubber conductive frame which not only has an excellent electrical conductivity and electromagnetic shielding property, but also deforms slightly according to different requirements. It has a good flexibility and adhesiveness, and a low cost.

In one embodiment of the present disclosure, a position on the base of the substrate 5 corresponding to the rubber conductive frame is arranged with a dispensing groove for fixing the rubber conductive frame onto the base of the substrate 5, and shape of the dispensing groove is identical to the shape of the bottom surface of the rubber conductive frame. In one embodiment of the present disclosure, the rubber conductive frame is fixed within the dispensing groove by extrusion or adhesion techniques. Due to the excellent flexibility and adhesiveness of the rubber conductive frame, it can be closely engaged into dispensing groove on the base of the substrate by extrusion or adhesion.

In one embodiment of the present disclosure, the rubber conductive frame is located on the open side of the hood structure, and engaged to the ground element 7 by press fit. The electrical conductivity of the rubber conductive frame is increased by certain pressure. Thus, the rubber conductive frame is engaged closely to the ground element 7 by press fit, which not only forms a closed shielding space with the electronic component 2 and the substrate 5, but also provides an excellent electrical conductivity.

FIG. 2 is a schematic diagram of the structure of a heat radiation shielding device provided in another embodiment of the present disclosure. As shown in FIG. 2, the heat radiation shielding device further comprises a heat conductive layer 8 arranged within the hood structure as shown in FIG. 1. between the electronic components 2 and the substrate 5 of the heat sink 4, so as to establish an effective heat conduction channel between the heat radiating electronic component 2 and the heat sink 4, which greatly reduces the thermal contact resistance and makes the heat sink to perform a better heat radiating function. In one embodiment of the present disclosure, the heat conductive layer 8 adopts thermal interface materials, such as a heat conductive glue, a heat conductive pad or a heat conductive grease.

In one embodiment of the present disclosure, the thickness of the heat conductive layer 8 may be arranged differently according to different heights of the heat radiating electronic component 2. For example, when the conductive frame 3 contains a plurality of electronic components that need heat shielding, and these electronic components have different heights, the heat conductive layer 8 of different thicknesses can be arranged between the electronic components 2 of different heights and the substrate 5 of the heat sink 4. Certainly, the heat conductive layer 8 of the same thickness made from compressible flexible interface materials can be arranged between the electronic components 2 of different heights and the substrate 5 of the heat sink 4.

In one embodiment of the present disclosure, the heat sink 4 is made from aluminum. The aluminum material is relatively cheaper than the copper material, and it is light, such that the conductive frame 3 does not have to bear a great pressure when the heat sink 4 is pressed on the conductive frame 3.

In one embodiment of the present disclosure, after anodizing the surface of the heat sink 4, the base of the substrate 5 is applied with a metal coating. The conductive materials lose conductivity after being anodized. Therefore, the base required to be conductive is applied with the metal coating to restore its conductivity. In another embodiment, surfaces of the heat sink 4 other than the base are anodized, retaining the conductivity of the base. In the above two embodiments, the heat sink 4 is anodized to increase the surface blackness of the heat sink 4 and improve the heat discharge capacity.

In one embodiment of the present disclosure, copper is exposed on a surface of the ground element 7.

The weight of the heat sink 4 is pressed on the conductive frame 3, which renders the physical connection between the heat sink 4 and the conductive frame 3 insecure. In one embodiment of the present disclosure, a fixing component is arranged on the heat sink 4 or the circuit board 1 to fix the heat sink 4 onto circuit board 1. In one embodiment of the present disclosure, the fixing component comprises, but not limited to, bolt or jump ring. For example, mounting holes may be arranged at corresponding positions on the heat sink 4 and the circuit board 1, and bolts are inserted through the mounting holes on the heat sink 4 into corresponding mounting holes on the circuit board 1, and fixed by screwing nuts in from the circuit board side. A plurality of cassettes can be further arranged on the circuit board 1, fixing the heat sink 4 on the circuit board 1 by jump rings. It should be understood by those skilled in the art that many manners of fixing components other than the above ones exemplified in the embodiments can also be adopted, as long as the heat sink can be fixed onto the circuit board. The present disclosure would not exhaust all the possibilities.

In one embodiment of the present disclosure, the area of the substrate 5 is slightly greater than the area of the conductive frame 3. Such a structure design not only facilitates fixing the conductive frame 3 on the base of the substrate 5, but also benefits a quicker discharge of the heat generated by the heat radiating electronic component 2 to the ambient, increasing the heat radiating efficiency. Furthermore, when the area of the substrate 5 is greater than the area of the conductive frame 3, it facilitates installing the fixing component for fixing the substrate 5 and the circuit board circuit board 1 on the surrounding area of the substrate 5 extending beyond the area of the conductive frame 3, for example, installing bolts on the surrounding area to fix the heat sink 4 on the circuit board 1.

In the heat radiation shielding device provided in the present disclosure, the ground element, the conductive frame and the substrate of the heat sink form a shielding hood, allowing a direct heat discharge of the heat radiating components via the heat sink, which not only meets the requirement of shielding the electromagnetic wave, but also achieves a satisfactory heat discharge effect. Meanwhile, the substrate of the heat sink also used as the top of the shielding hood saves the material.

The above are merely preferable embodiments of the present disclosure, and not intended for limiting the disclosure. Any amendment or equivalent alternation made within the spirit and principle of the present disclosure should be covered within the protection scope of the present disclosure.

What is claimed is:

1. A heat radiation shielding device for shielding electronic components on a circuit board, comprising:
a heat sink, comprising a substrate with a conductive base and cooling fins arranged on the substrate;
a conductive frame, fixed on periphery of the base of the substrate of the heat sink, and forming a hood structure closed on three sides and open on one side together with the substrate of the heat sink; and
a ground element, arranged around the electronic components on the circuit board, wherein the conductive frame is arranged on the open side of the hood structure and engaged to the ground element, forming an electric connection with the circuit board.

2. The heat radiation shielding device according to claim 1, wherein the conductive frame is a rubber conductive frame.

3. The heat radiation shielding device according to claim 2, wherein a position on the base of the substrate corresponding to the rubber conductive frame is arranged with a dispensing groove for fixing the rubber conductive frame onto the base of the substrate, and the rubber conductive frame is fixed within the dispensing groove by extrusion or adhesion techniques.

4. The heat radiation shielding device according to claim 2, wherein the rubber conductive frame is located on the open side of the hood structure, and engaged to the ground element by press fit.

5. The heat radiation shielding device according to claim 1, further comprising a heat conductive layer arranged within the hood structure between the electronic components and the substrate of the heat sink, wherein the heat conductive layer is a heat conductive glue, a heat conductive pad or a heat conductive grease.

6. The heat radiation shielding device according to claim 1, wherein the heat sink is made from aluminum.

7. The heat radiation shielding device according to claim 1, wherein after anodizing the surface of the heat sink, the base of the substrate is applied with a metal coating.

8. The heat radiation shielding device according to claim 1, wherein surfaces of the heat sink other than the base of the substrate are anodized.

9. The heat radiation shielding device according to claim 1, wherein an area of the substrate of the heat sink is greater than an area of the conductive frame.

10. The heat radiation shielding device according to claim 1, wherein copper is exposed on a surface of the ground element.
